(19) United States
(12) Patent Application Publication
(10) Pub. No.: US 2004/0000334 A1
(43) Pub. Date: Jan. 1, 2004

(54) Photovoltaic tiles, roofing system, and method of constructing roof

(75) Inventor: Stephen Ressler, Wilmington, DE (US)

Correspondence Address: BURR & BROWN, PO BOX 7068, SYRACUSE, NY, 13261-7068, US

(73) Assignee: AstroPower, Inc., Newark, DE

(21) Appl. No.: 10/608,201

(22) Filed: Jun. 27, 2003

Related U.S. Application Data
(60) Provisional application No. 60/392,341, filed on Jun. 27, 2002.

(51) Int. Cl. H01L 25/00

(52) U.S. Cl. 136/251; 52/173.3

(57) ABSTRACT

There are provided photovoltaic tiles (each containing at least one photovoltaic cell) which can be readily integrated into a roof structure constructed of standard roofing materials. The photovoltaic tiles have frames which hold photovoltaic elements, the frames having end portions which are engageable with opposite end portions of similarly-shaped photovoltaic tiles and/or with end portions of standard roofing tiles, and/or which are shaped similar to shapes of end portions of standard roofing tiles. There are also provided roofing systems including standard roofing tiles and such photovoltaic tiles. There are also provided methods of constructing a roof using such a roofing system.

### CROSS-REFERENCE TO RELATED APPLICATIONS

This application claims the benefit of U.S. Provisional Patent Application No. 60/392,341, filed Jun. 27, 2002, the entirety of which is incorporated herein by reference.

### FIELD OF THE INVENTION

The present invention is directed to photovoltaic tiles in which each photovoltaic tile contains one or more photovoltaic cells, and which can be integrated into a roof structure constructed of standard roofing materials. The present invention is further directed to a roofing system including standard roofing tiles and one or more photovoltaic tiles of the present invention. The present invention is also directed to a method of constructing a roof using a roofing system according to the present invention.

### BACKGROUND OF THE INVENTION

Solar energy collection is of great importance and is of ever-increasing importance, particularly in light of limitations and environmental concerns associated with other sources of energy, and the resulting ever-increasing demand for “alternative” energy (i.e., non-fossil fuel energy).

Photovoltaic modules have been deployed in a wide variety of ways, including deployment on the roofs of buildings, including private homes. However, such panels have not been capable of being readily integrated into roof structures constructed of standard roofing materials, placing a limitation on the usage of photovoltaic modules in a variety of locations where solar energy could otherwise be collected. For example, many communities prohibit the mounting of conventional photovoltaic modules on the front roofs of homes because the conventional photovoltaic modules cannot be effectively integrated into roof structures constructed of standard roofing materials.

### BRIEF SUMMARY OF THE INVENTION

In accordance with the present invention, there are provided photovoltaic tiles (each containing at least one photovoltaic cell) which can be readily integrated into a roof structure constructed of standard roofing materials. The present invention is further directed to a roofing system including standard roofing tiles and one or more photovoltaic tiles of the present invention. The present invention is also directed to a method of constructing a roof using a roofing system according to the present invention. The present invention provides roofs in which photovoltaic tiles are securely fastened to the roof, in which the photovoltaic tiles lay close to the roof surface, and/or in which the photovoltaic tiles provide a high degree of uniformity and similarity in dimension to the roofing tiles. These structural features make it possible to integrate the photovoltaic tiles of the present invention with standard roofing tiles to provide an integrated structure which is aesthetically improved compared to conventional photovoltaic options.

According to the present invention, there is provided a photovoltaic tile which has at least one end portion which is engageable with an end portion of another similarly-shaped photovoltaic tile and/or an end portion of a standard roofing tile.

In one aspect of the present invention, there is provided a photovoltaic tile which has first and second end portions which have respective shapes which are substantially identical to the shapes of first and second side portions of a standard roofing tile, such first and second side portions being shaped such that a first side portion of one of such standard roofing tiles is engageable with a second side portion of a second such standard roofing tile.

The present invention is directed to a photovoltaic tile, comprising at least one photovoltaic element having at least one photovoltaic collection surface; and a frame extending around an edge of the photovoltaic element, the frame holding the photovoltaic element in place relative to the frame.

In one aspect of the present invention, the frame comprises a first end portion having a shape which is engageable with a shape of the second end portion, such that a pair of photovoltaic elements can be engaged with each other by engaging the first end portion of one with the second end portion of the other.

In another aspect of the present invention, the frame comprises a first end portion having a shape which is engageable with at least a first side portion of a standard roofing tile. Preferably, the frame further comprises a second end portion having a shape which is engageable with a second side portion of the standard roofing tile.

In a further aspect of the present invention, the frame comprises a first end portion having a shape which is similar to at least a first side portion of a standard roofing tile.

In addition, the present invention is directed to a roofing system comprising a plurality of roofing tiles and at least one photovoltaic tile as described above. The present invention is further directed to a roofing system which further comprises a roof deck on which the roofing tiles and the at least one photovoltaic tile are mounted, and preferably also a support structure on which the roof deck is supported.

The photovoltaic elements described above preferably each comprise at least one photovoltaic cell mounted in a casing. Preferably, the photovoltaic elements each have a dead space in order to provide an overlap, e.g., an area where a portion of a tile in a row (course) of tiles mounted lower on a roof is overlapped by portions of tiles in a course mounted farther up the roof.

In a preferred aspect of the present invention, the width of the frame (i.e., the dimension in the direction in which the tiles in a course are arranged) is a multiple of the width of the roofing tile, so that each photovoltaic element can be mounted so as to occupy an area where one or more roofing tiles would fit, thereby providing the ability to provide continuity in an overall pattern of a roof structure which includes roofing tiles and photovoltaic tiles.

The present invention is further directed to a method of constructing a roof, comprising positioning on a roof surface at least one roofing tile having a first side portion and a second side portion and at least one photovoltaic tile, such that a first end portion of the frame of the photovoltaic tile is engaged with a first side portion of the roofing tile.

The present invention is further directed to a method of constructing a roof, comprising positioning on a roof surface at least a first photovoltaic tile and a second photovoltaic tile, such that a second end portion of the frame of the second photovoltaic tile is engaged with a first end portion of the frame of the first photovoltaic tile.

In addition, the present invention is directed to a method of constructing a roof, comprising positioning on a roof surface a plurality of roofing tiles and a plurality of photovoltaic tiles, each of the roofing tiles having a first side portion and a second side portion, each of the photovoltaic tiles comprising a frame having a first end portion and a second end portion, such that each first end portion is engaged with a second end portion of another frame or with a second side portion of one of the roofing tiles, and such that each second end portion is engaged with a first end portion of another frame or a first side portion of one of the roofing tiles.

The invention may be more fully understood with reference to the accompanying drawings and the following description of the embodiments shown in those drawings. The invention is not limited to the exemplary embodiments and should be recognized as contemplating all modifications within the skill of an ordinary artisan.

### BRIEF DESCRIPTION OF THE DRAWING FIGURES

FIG. 1 is a schematic view of a preferred embodiment of the top of a photovoltaic element which is suitable for use according to the present invention.

FIG. 2 is a perspective view of an example of a standard roofing tile.

FIG. 3 is a perspective view of a front end of a first embodiment of a frame according to the present invention.

FIG. 4 is a perspective view of the back side of the front frame member of FIG. 3.

FIG. 5 is a cross-sectional view of a left end portion of a first photovoltaic tile, a roofing tile engaged with the first photovoltaic tile, and a right end portion of a second roofing tile engaged with the roofing tile, according to a second embodiment of a frame according to the present invention.

FIG. 6 is a cross-sectional view of a front portion of a frame of a photovoltaic tile according to the second embodiment.

FIG. 7 is a cross-sectional view of a rear portion of a frame of a photovoltaic tile according to the second embodiment.

FIG. 8 is a cross-sectional view of a left end portion of a first photovoltaic tile, a roofing tile engaged with the first photovoltaic tile, and a right end portion of a second roofing tile engaged with the roofing tile, according to a third embodiment of a frame according to the present invention.

FIG. 9 is a cross-sectional view showing a roofing tile applied to a roof in one course, a photovoltaic tile applied to the roof in a next course, and a second photovoltaic tile applied to the roof in a further course.

FIG. 10 is a perspective view depicting photovoltaic tiles engaged with other photovoltaic tiles, photovoltaic tiles engaged with roofing tiles, and a roofing tile engaged with another roofing tile.

### DETAILED DESCRIPTION OF THE INVENTION

As mentioned above, the present invention provides photovoltaic tiles (each containing at least one photovoltaic cell) which can be readily integrated into a roof structure constructed of standard roofing materials.

The photovoltaic tiles according to the present invention each include at least one photovoltaic element and a frame which holds the photovoltaic element in place relative to the frame.

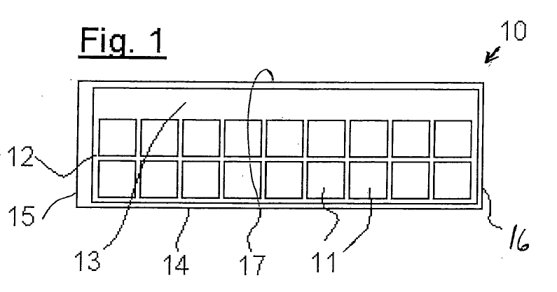

FIG. 1 depicts a preferred embodiment of a photovoltaic element 10 which is suitable for use according to the present invention. In the photovoltaic element 10 shown in FIG. 1, eighteen photovoltaic cells 11 are encapsulated in a transparent casing 12, preferably made of glass. The photovoltaic element 10 shown in FIG. 1 includes a dead space 13, where no photovoltaic cells or portions of photovoltaic cells are present.

A variety of photovoltaic cells are known in the art, e.g., structures which can separate charges, such as p-i-n devices, photo-electrochemical devices (e.g., Grätzel Cells, such as those disclosed in U.S. Pat. Nos. 4,927,721 and 5,084,365, the entireties of which are hereby incorporated by reference) and p/n junction devices, as well as quantum dot devices which separate charges due to differences in recombination rates between electrons and holes. The invention is applicable to these and any other photovoltaic cells.

In the case of p/n junction devices, as is well known, a photovoltaic cell comprises at least one diode comprising at least one n-type region and at least one p-type region. The ntype region and the p-type region are in contact with each other, so as to form a p-n junction. In order to maximize the surface area of solar collection, photovoltaic cells typically have a substantially flat surface which faces the source of light (e.g., the sun).

Typically, such photovoltaic elements further include n-type region and p-type region contact layers, an antireflective, substantially transparent coating over the n-region contact layer, a transparent cover glass over the antireflective coating, a junction box, and electrical lead lines (often referred to as “pigtails”), all of which are well known in the art. The electrical lead lines of a number of photovoltaic elements can be connected (e.g., using “quick connectors”) in series to combine the power produced by such photovoltaic elements.

The photovoltaic element 10 depicted in FIG. 1 has a frame which has a front edge 14, a left edge 15, a right edge 16 (opposite the left edge 15), a back edge 17 (opposite the front edge 14), a photovoltaic collection surface (on the top, facing out of the page) and a bottom surface (opposite the photovoltaic collection surface). A junction box can be positioned at any suitable location as is well known in the art, e.g., on the bottom of the photovoltaic element.

The frame preferably extends around an edge of the at least one photovoltaic element, and holds the at least one photovoltaic element in place relative to the frame. In one aspect of the present invention, the frame comprises a first end portion and a second end portion, the first end portion having a shape which is engageable with a shape of the second end portion, such that a pair of such photovoltaic elements can be engaged with each other by engaging the first end portion of one with the second end portion of the other.

In another aspect of the present invention, the frame comprises a first end portion having a shape which is engageable with at least a first side portion of a standard roofing tile. Preferably, the frame further comprises a second end portion having a shape which is engageable with a second side portion of the standard roofing tile.

In a further aspect of the present invention, the frame comprises a first end portion having a shape which is similar to at least a first side portion of a standard roofing tile. Preferably, the frame further comprises a second end portion having a shape which is similar to a second side portion of the standard roofing tile.

The frame according to the present invention can be made of any suitable material. For example, the frame is preferably made of aluminum.

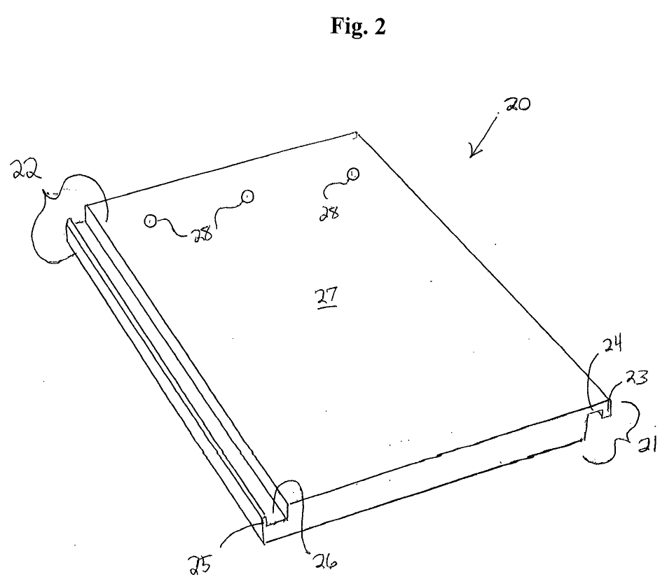

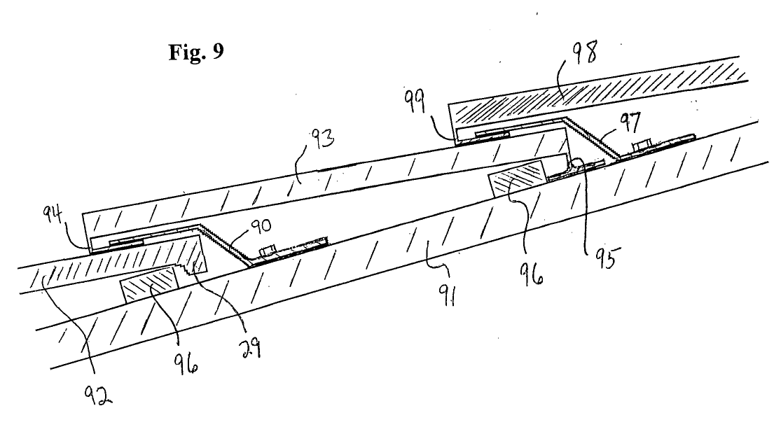

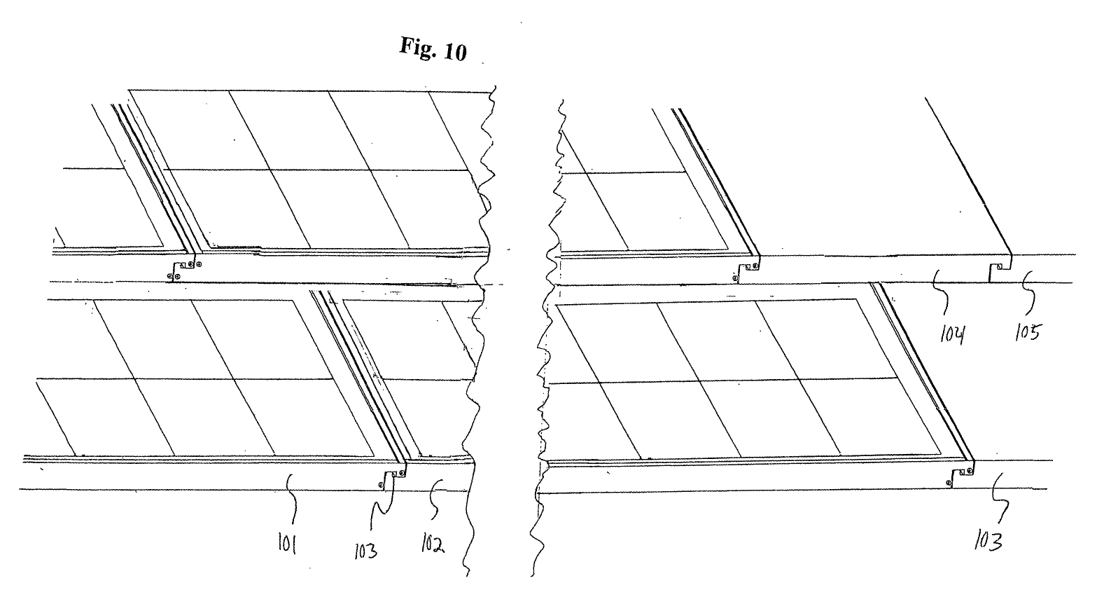

FIG. 2 depicts an example of a standard roofing tile 20, made, e.g., of concrete. The tile 20 depicted in FIG. 2 has a right side portion 21 and a left side portion 22. The right side portion 21 includes an overhang portion 23 and an overlay portion 24. The left side portion 22 includes an upright portion 25 and a trough portion 26. When installing such roofing tile, a first tile is positioned on the roof with its top surface 27 away from the roof, and then a second tile is positioned on the roof, also with its top surface 27 away from the roof, such that the right side portion 21 of the second tile engages with the left side portion 22 of the first tile, whereby the overlay portion 24 of the second tile is adjacent to or in contact with the upright portion 25 of the first tile, and the overhang portion 23 of the second tile is adjacent to or in contact with the trough portion 26 of the first tile. In some cases, each tile includes a bottom hanging portion (see reference no. 29 in FIG. 9) which hangs over a batten (see reference nos. 96 in FIG. 9) which has been attached to the roof deck, in order to assist in holding the tiles on the roof. In the tile 20 shown in FIG. 2, there are further provided holes 28 through which screws, nails, bolts or any other attachment element can be inserted and driven into or otherwise engaged with the roof deck to assist in holding the tiles on the roof. Furthermore, one or more retaining clips (see reference nos. 90 and 97 in FIG. 9) can be attached to the roof deck, the retaining clips including a portion which covers a portion of the top surface 27 (preferably on the end remote from where the holes 28 are shown), to assist in holding the tiles on the roof (e.g., in high winds).

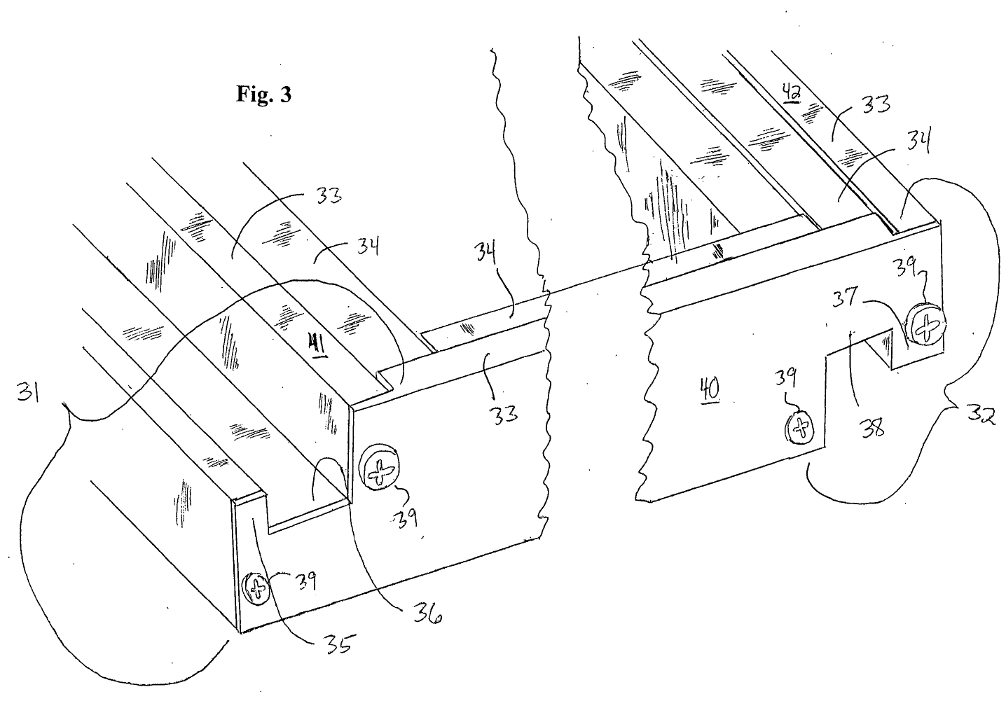

FIG. 3 depicts a front end of a first embodiment of a frame according to the present invention, suitable for use in making photovoltaic tiles which can be used, together with roofing tiles, e.g., tiles 20 as shown in FIG. 2, in constructing a roof. The frame includes a left end portion 31 and a right end portion 32. FIG. 3 also shows top elements 33 of the frame and lower elements 34. The photovoltaic element (not shown in FIG. 3) is positioned between the top elements 33 and the lower elements 34, the top elements 33 and the lower elements 34 supporting the photovoltaic element and serving to assist in holding the photovoltaic element in place. The left end portion 31 includes an upright portion 35 and a trough portion 36. The right end portion 32 includes an overhang portion 37 and an overlay portion 38. Screws 39 connect the front frame member 40 to the left frame member 41 and the right frame member 42.

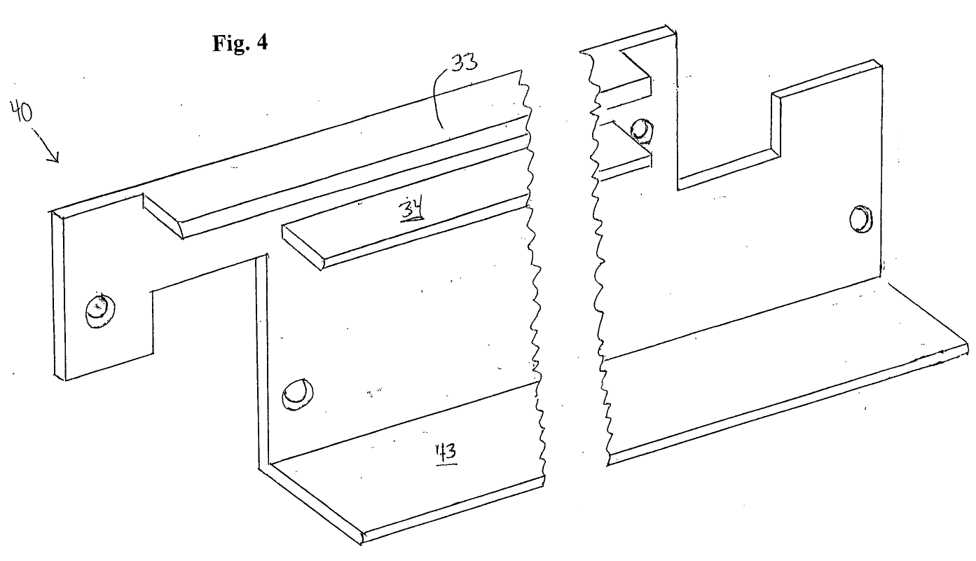

FIG. 4 is a view of the back side (i.e., the side opposite the front face shown in FIG. 3) of the front frame member 40. FIG. 4 shows a stiffening rib 43.

As used herein, the expression hook shape includes a shape which has a body portion, a hook portion and a connecting portion which connects the body portion and the hook portion, the hook portion being spaced from the body portion in a first direction, the hook portion having at least one dimension which is larger in a transverse direction perpendicular to the first direction than a corresponding dimension on the connecting portion in the same transverse direction. As used herein, a statement that a first structure has a hook shape which is engageable (or engaged) with a hook shape attached to a second structure means that the respective hook shapes are shaped such that they can be engaged with each other so as to prevent the separate structures being from separated from each other by either or both structures being moved in the “first” direction (as defined above).

As used herein, the expression upward hook shape includes a shape which has an upward hook portion which extends away from a main surface, the upward hook portion including an upwardly extending portion and a connecting portion, the connecting portion connecting the upwardly extending portion to the main surface. For example, the left side portion 22 of the tile 20 depicted in FIG. 2 has an upward hook shape, as does the left end portion 31 of the first embodiment of a frame according to the present invention, depicted in FIG. 3.

As used herein, the expression downward hook shape includes a shape which has a downward hook portion which extends away from a main surface, the downward hook portion including a downwardly extending portion and a connecting portion, the connecting portion connecting the downwardly extending portion to the main surface. For example, the right side portion 21 of the tile 20 depicted in FIG. 2 has a downward hook shape, as does the right end portion 32 of the first embodiment of a frame according to the present invention, depicted in FIG. 3.

When installing a photovoltaic tile as depicted in FIGS. 3 and 4 adjacent to a roofing tile 20 as shown in FIG. 2, the photovoltaic tile is positioned on the roof such that the right end portion 32 of the frame of the photovoltaic tile engages with the left side portion 22 of the first tile, whereby the overlay portion 38 of the frame of the photovoltaic tile is adjacent to or in contact with the upright portion 25 of the roofing tile, and the overhang portion 37 of the photovoltaic tile is adjacent to or in contact with the trough portion 26 of the roofing tile.

When installing a second photovoltaic tile as depicted in FIGS. 3 and 4 adjacent to a first photovoltaic tile as depicted in FIGS. 3 and 4, the second photovoltaic tile is positioned on the roof such that the right end portion 32 of the frame of the second photovoltaic tile engages with the left side portion 31 of the frame of the first photovoltaic tile, whereby the overlay portion 38 of the frame of the second photovoltaic tile is adjacent to or in contact with the upright portion 35 of the frame of the first photovoltaic tile, and the overhang portion 37 of the frame of the second photovoltaic tile is adjacent to or in contact with the trough portion 36 of the frame of the first photovoltaic tile.

In FIGS. 5-7, a second embodiment of a frame according to the present invention is depicted.

FIG. 5 depicts profiles of a left end portion 51 and a right end portion 52 of the second embodiment of a frame according to the present invention, suitable for use in making photovoltaic tiles which can be used, together with roofing tiles, in constructing a roof. The left end portion 51 provides an upward hook shape element which is engaged with a right end portion of a roofing tile 53, and the right end portion 52 provides a downward hook shape element which is engaged with a left end portion of a roofing tile 54. The left end portion 51 and the right end portion 52 depicted in FIG. 5 each include a channel 55, which serves to catch moisture, if any penetrates between the frame and the photovoltaic element, and cause the moisture to drain out through the front of the photovoltaic tile. The right end portion 52 shown in FIG. 5 is engageable with the left end portion of a second frame having a profile as shown in FIG. 5.

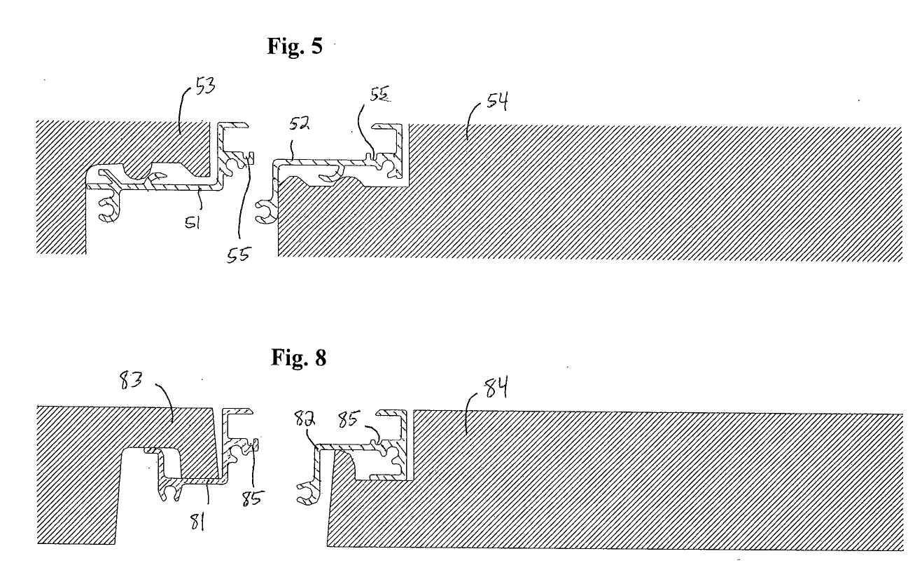

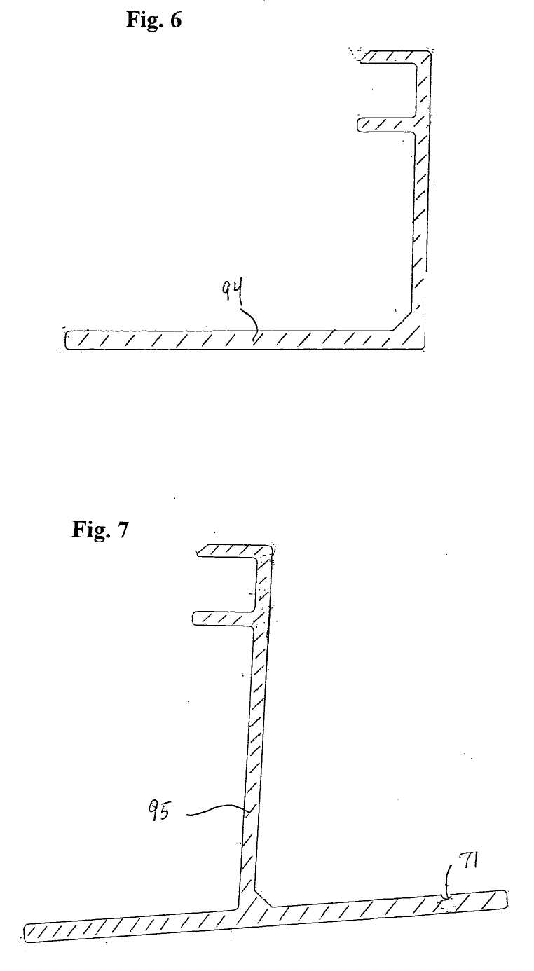

FIG. 6 is a profile of a front portion of the second embodiment of a frame according to the present invention.

FIG. 7 is a profile of a rear portion of the second embodiment of a frame according to the present invention. The rear portion includes holes 71 for receiving screws, nails, bolts or other connectors which serve to attach the frame to the roof deck.

FIG. 8 depicts profiles of a left end portion 81 and a right end portion 82 of a third second embodiment of a frame according to the present invention, suitable for use in making photovoltaic tiles which can be used, together with roofing tiles, in constructing a roof. The left end portion 81 provides an upward hook shape element which is engaged with a right end portion of a roofing tile 83, and the right end portion 82 provides a downward hook shape element which is engaged with a left end portion of a roofing tile 84. The left end portion 81 and the right end portion 82 depicted in FIG. 8 each include a channel 85, which serves to catch moisture, if any penetrates between the frame and the photovoltaic element, and cause the moisture to drain out through the front of the photovoltaic tile. The right end portion 82 shown in FIG. 8 is engageable with the left end portion of a second frame having a profile as shown in FIG. 8.

The respective end portions of the frames according to the present invention can be made of shapes which correspond to the shapes of the side portions of any suitable roofing tile, a wide variety of which are known, e.g., various types of “shake” tile, concrete tile, “S” tiles (e.g., made of terra cotta), W tiles (e.g., made of terra cotta), etc.

In a preferred aspect of the present invention, the width of the frame (i.e., the distance between respective end portions) is a multiple of the width of the roofing tile to which the end portions of the frame correspond, so that each photovoltaic element can be mounted so as to occupy an area which is the same or substantially the same as the area which would be occupied by a corresponding number (i.e., equal to the multiple) of roofing tiles, thereby providing the ability to provide continuity in an overall pattern of a roof structure which includes roofing tiles and photovoltaic tiles.

Preferably, sealant material is applied between the frame and the photovoltaic element to avoid seepage of water therebetween. Suitable sealant materials include, e.g., adhesives, preferably liquid adhesives, such as silicone sealant.

The present invention is also directed to a method of constructing a roof using a roofing system according to the present invention.

In accordance with the present invention, at least one photovoltaic tile is laid down on a roof together with a plurality of roofing tiles. Preferably, a layer of fire barrier roofing material is secured to the roof deck prior to laying down the tiles (i.e., the at least one photovoltaic tile and the roofing tiles), so that the fire barrier roofing material is positioned between the roof deck and the tiles. Preferably, the layer of fire barrier roofing material is class C or better, e.g., class C, class B or class A. In such a case, the fire barrier roofing material preferably acts as the primary fire barrier and the secondary weather barrier, while the tiles act as the primary weather barrier. Any suitable type of barrier roofing material can be employed, a variety of which are known in the building construction art, e.g., composite or asphalt shingles.

In a first embodiment of a method according to the present invention, a roof deck is attached to a support structure using nails, screws, bolts or any other suitable attachment members, as is well known in the building construction art. The support structure can be any suitable building material, e.g., wood. The roof deck can likewise be any suitable building material, e.g., plywood or OSB.

In the first embodiment of a method, next, a layer of composite shingles is applied to the roof deck, as is well known in the building construction art.

One or more battens are preferably secured to the roof before applying the tiles, preferably after applying fire barrier roofing material to the roof so that the one or more battens (e.g., a 1 inch by 2 inch strip of wood) are positioned between the fire barrier roofing material and the tiles. In such a case, the roofing tiles and/or the photovoltaic tiles preferably have an anchor portion (e.g., on which a roofing tile which has a bottom hanging portion can be engaged) which abuts the batten to serve to assist in holding the tile in place on the roof.

In the first embodiment of a method, a plurality of battens are positioned on the composite shingles and attached to the roof deck.

Preferably, at least a first course of roofing tiles are applied along the bottom edge of the roof, and then a second course of roofing tiles are applied just above the first course, with a consistent amount of overlap. A typical roofing tile extends about 17 inches in the direction toward the apex of the roof, and in such a case, the overlap is preferably from about 3 to about 4 inches. Providing leeway in the amount of overlap increases the possibility that a uniform overlap can be applied in the ascending courses of tiles, such that tiles completely cover the roof and each tile has approximately the same reveal length (i.e., the exposed area of each tile has approximately the same dimension in the direction ascending the slope of the roof). With roofing tiles having a right side portion which fits into the left side portion of a similar roofing tile, application of a course of tiles moves from right to left across the roof.

Preferably, each course of tiles which includes photovoltaic tiles includes at least two roofing tiles at both ends of the course. Preferably, with roofing tiles having a right side portion which fits into the left side portion of a similar roofing tile, and corresponding photovoltaic tiles having a right end portion which fits into the left side portion of a corresponding roofing tile or into the left end portion of a similar photovoltaic tile, moving from right to left across the roof, at least two roofing tiles are applied, then the photovoltaic tiles are applied, and then at least two more roofing tiles are applied, completing the course of tiles. However, it should be appreciated that any desired pattern of roofing tiles and photovoltaic tiles can be made, and the roofing tiles and photovoltaic tiles can be applied in any desired sequence.

Preferably, at least two courses of roofing tiles are applied adjacent to the apex of the roof. Thus, a preferred pattern includes a border at least two roofing tiles deep along the outer periphery of the roof, and the inner region defined by the border containing or consisting of photovoltaic tiles.

Preferably, the tiles in each course are offset from the tiles in the immediately adjacent course or courses. For example, a first course of tiles is applied, and then the tiles in the second course of tiles are applied such that the gaps between respective tiles in the second course are offset from the gaps between respective tiles in the first course. Preferably, the distance of the offset is approximately half of the width of the roofing tiles, i.e., half the length of the edges which are parallel to the bottom edge of the roofline.

Preferably, one or more retaining clips for each photovoltaic tile are attached to the roof deck prior to positioning such photovoltaic tile on the roof. For example, FIG. 9 shows a retaining clip 90 which is bolted into the roof deck 91 such that the free end of the retaining clip 90 projects over the roofing tile 92 from the previous course. After all the retaining clips for the photovoltaic tile 93 have been attached (or the retaining clip, where only one retaining clip is used for each photovoltaic tile), the photovoltaic tile 93 is moved into position on the roof, with the free end of each retaining clip sliding between the frame of the photovoltaic tile 93 and an underhang portion 94 (an underhang portion 94 is shown in FIG. 6 also) which is integral with or rigidly attached to the front portion of the frame of the photovoltaic tile 93.

FIG. 9 also shows battens 96 attached to the roof deck 91.

Preferably, the frame includes a flange portion 95 (a flange portion 95 is shown in FIG. 6 also) having at least one hole, for receiving a nail, screw, bolt or other attachment element which serves to attach the frame to the roof deck.

After the course of tiles which includes the photovoltaic tile 93 has been completed, retaining clips 97, for the next course of tiles, are attached to the roof deck 91. The free end of the retaining clip 97 projects over the photovoltaic tile 93 from the previous course. After all the retaining clips for the photovoltaic tile 98 have been attached, the photovoltaic tile 98 is moved into position on the roof, with the free ends of the retaining clips sliding between the frame of the photovoltaic tile 98 and the underhang portion 99 which is integral with or rigidly attached to the front portion of the frame of the photovoltaic tile 98.

In the embodiment shown in FIG. 9, the underhang portion 99 extends parallel to the free end of the retaining clip 97 for a distance which makes it possible to mount the tile 98 so as to provide the desired “reveal” (i.e., the exposed area) of the tile 93 below. Preferably, the reveal of each tile is in the range of from about 13 to about 14 inches. The retaining clip serves, e.g., to prevent uplift in windy conditions.

Preferably, as each photovoltaic tile is positioned, it is wired such that energy (from the conversion by the photovoltaic element of light energy into electrical energy) can be collected. In a preferred aspect of the invention, each photovoltaic tile has a pair of output wires, and as each photovoltaic tile is installed, its output wires are connected to collection wires so that the photovoltaic tiles are connected in series to collection wires. One end of each of the collection wires preferably extends through the roof deck and into the interior of the building, e.g., to be connected to an inverter. Preferably, a structure is provided whereby the space in the roof deck through which the collection wires pass is prevented from leaking, e.g., by use of an elbow structure with a bulkhead, such structures being known in the art.

Preferably, the photovoltaic tiles are grounded, e.g., by using a ground wire which is connected to the respective frames of each of the photovoltaic elements. In such a case, the photovoltaic tiles are preferably connected to the ground wire sequentially as the photovoltaic tiles are installed.

Preferably, when a photovoltaic tile according to the present invention is engaged with an adjacent photovoltaic tile or roofing tile, space is provided which can accommodate expansion and shrinkage of the frame. For example, FIG. 10 shows a pair of photovoltaic tiles 101, 102 engaged with each other, in which the right end portion of the photovoltaic tile 101 is engaged with the left end portion of the photovoltaic tile 102. As shown in FIG. 10, space 103 is present between the frames which can accommodate lateral expansion and contraction of the respective frames. FIG. 10 also shows a right end portion of photovoltaic tile 102 engaged with a left side portion of a roofing tile 103, and, in a different course, a roofing tile 104 having a right side portion engaged with a left side portion of a roofing tile 105. From FIG. 10, it can be seen that water which enters the space between the roofing tile 104 and the roofing tile 105 will tend to flow along that space (i.e., will not escape the trough portion of roofing tile 105 over the upright portion of the roofing tile 105) until it reaches the lower end of that course of tiles, and then run out onto the roofing tile 103. Similarly, water which enters the space between the roofing tile 103 and the photovoltaic tile 102 will tend to flow along that space (i.e., will not escape the trough portion over the upright portion of the left side portion of the roofing tile 103) until it reaches the lower end of that course of tiles, and then run out onto the tiles in the course below. Similarly, water which enters a space between a pair of photovoltaic tiles will tend to flow in that space (i.e., will not escape the trough portion over the upright portion of the left side portion of the photovoltaic tile). In such a way, the combination of roofing tiles and photovoltaic tiles provides an effective primary weather barrier.

In accordance with one modification of the present invention, some or all of the end portions of photovoltaic tiles which are engaged with end portions of other photovoltaic tiles have shapes which differ from the end portions of photovoltaic tiles which are engaged with side portions of roofing tiles. Therefore, where a series of photovoltaic tiles are connected to one another, it is only the end portions of the photovoltaic tiles in that series which engage with roofing tiles that need to be shaped similar to the corresponding end portions of the roofing tiles. In this modification, three types of photovoltaic tiles are provided, one type for engaging a photovoltaic tile on its right end and a roofing tile on its left end, a second type for engaging a photovoltaic tile on its right end and a photovoltaic tile on its left end, and a third type for engaging a roofing tile on its right end and a photovoltaic tile on its left end.

Preferably, each frame may include one or more drain holes or notches for the purpose of allowing any moisture which may have penetrated into the photovoltaic tile to escape and/or to pass through the frame along the surface of the roof deck.

Preferably, the photovoltaic tiles are constructed and/or mounted so as to remain as cool as possible (i.e., to minimize temperature rise) using any suitable technique, a wide variety of which are well known to those of skill in the art. For example, one such technique is to employ conventional counter-battens, i.e., a first series of battens mounted on the roof deck and running up the roof deck perpendicular to the roof apex, and a second series of battens mounted on the first series of battens and perpendicular to the first series of battens (i.e., parallel to the roof apex), and then to mount the tiles on the second series of battens.

Although the photovoltaic tiles, roofing systems and methods of constructing roofs in accordance with the present invention have been described in connection with preferred embodiments, it will be appreciated by those skilled in the art that modifications not specifically described may be made without departing from the spirit and scope of the invention defined in the following claims. For example, any two or more structural parts of the photovoltaic tiles and/or roofing systems can be integrated; any structural part of the photovoltaic tiles and/or roofing systems can be provided in two or more parts (which are held together, if necessary).

1. A photovoltaic tile, comprising:
at least one photovoltaic element having at least one photovoltaic collection surface; and
a frame holding said at least one photovoltaic element such that said at least one photovoltaic element is substantially held in place relative to said frame,
said frame comprising a first end portion and a second end portion, said first end portion being of a shape which is engageable with a shape of said second end portion.

2. A photovoltaic tile as recited in claim 1, wherein said frame comprises a front frame surface and a back frame surface, said front frame surface and said back frame surface each having a length which is a multiple of a length of a standard roofing tile.

3. A photovoltaic tile as recited in claim 1, wherein said first end portion comprises an upward hook shape, and said second end portion comprises a downward hook shape.

4. A photovoltaic tile, comprising:
at least one photovoltaic element having at least one photovoltaic collection surface; and
a frame holding said at least one photovoltaic element such that said at least one photovoltaic element is substantially held in place relative to said frame,
said frame comprising a first end portion having a shape which is engageable with at least a first side portion of a standard roofing tile.

5. A photovoltaic tile as recited in claim 4, wherein said frame further comprises a second end portion having a shape which is engageable with a shape of said first end portion.

6. A photovoltaic tile as recited in claim 4, wherein said frame further comprises a second end portion having a shape which is engageable with a second side portion of said standard roofing tile.

7. A photovoltaic tile as recited in claim 4, wherein said frame comprises a front frame surface and a back frame surface, said front frame surface and said back frame surface each having a length which is a multiple of a length of said standard roofing tile.

8. A photovoltaic tile, comprising:
at least one photovoltaic element having at least one photovoltaic collection surface; and
a frame holding said at least one photovoltaic element such that said at least one photovoltaic element is substantially held in place relative to said frame,
said frame comprising a first end portion having a shape which is similar to at least a shape of a first side portion of a standard roofing tile.

9. A photovoltaic tile as recited in claim 8, wherein said frame further comprises a second end portion having a shape which is similar to a shape of a second side portion of said standard roofing tile.

10. A photovoltaic tile as recited in claim 8, wherein said frame comprises a front frame surface and a back frame surface, said front frame surface and said back frame surface each having a length which is a multiple of a length of a standard roofing tile.

11. A roofing system, comprising:
at least one photovoltaic tile as recited in claim 6, said photovoltaic tile further comprising at least one underhang portion attached to or integral with said frame; and
at least one retaining clip, said retaining clip comprising an underhang engaging portion having a thickness which is smaller than a thickness of a space between said underhang portion and said frame.

12. A roofing system as recited in claim 11, wherein said retaining clip has a first substantially flat portion for engagement with a roof deck, an underhang engaging portion for fitting between said underhang portion and said frame, and a third portion connecting said first portion to said underhang engaging portion.

13. A roofing system, comprising:
a plurality of roofing tiles, each said roofing tile having a first side portion and a second side portion; and
at least one photovoltaic tile as recited in claim 6.

14. A roofing system, comprising:
at least one photovoltaic tile as recited in claim 9, said photovoltaic tile further comprising at least one underhang portion attached to or integral with said frame; and
at least one retaining clip, said retaining clip comprising an underhang engaging portion having a thickness which is smaller than a thickness of a space between said underhang portion and said frame.

15. A roofing system as recited in claim 14, wherein said retaining clip has a first substantially flat portion for engagement with a roof deck, said underhang engaging portion for fitting between said underhang portion and said frame, and a third portion connecting said first portion to said underhang engaging portion.

16. A roofing system, comprising:
a plurality of roofing tiles, each said roofing tile having a first side portion and a second side portion; and
at least one photovoltaic tile as recited in claim 9.

17. A method of constructing a roof, comprising:
positioning at least one roofing tile on a roof surface, said at least one roofing tile having a first side portion; and
positioning at least a first photovoltaic tile on said roof surface, said first photovoltaic tile comprising a first photovoltaic element and a first frame, said first frame holding said first photovoltaic element such that said first photovoltaic element is substantially held in place relative to said first frame, said first frame comprising a first end portion, such that said first end portion of said first frame is engaged with said first side portion of said at least one roofing tile.

18. A method as recited in claim 17, further comprising attaching at least one retaining clip to said roof deck, said frame having an underhang portion attached thereto, and while positioning said at least one photovoltaic tile on said roof surface, a free end of said retaining clip slides between said frame and said underhang portion.

19. A method as recited in claim 18, wherein an underhang engaging portion of said retaining clip overlaps only a portion of said underhang portion, whereby a first photovoltaic tile in one course can be mounted on said roof surface above a second photovoltaic tile in a different course such that a desired reveal length of said second photovoltaic tile is not overlapped by said first photovoltaic tile.

20. A method as recited in claim 17, further comprising:
positioning at least a second photovoltaic tile on said roof surface, said second photovoltaic tile comprising at least a second photovoltaic element and a second frame, said second frame holding said second photovoltaic element such that said second photovoltaic element is substantially held in place relative to said second frame, said second frame comprising a second frame first end portion and a second frame second end portion,
such that said second frame first end portion is engaged with a second end portion of said first frame.
